(19) United States
(12) Patent Application Publication
(10) Pub. No.: US 2012/0293950 A1
(43) Pub. Date: Nov. 22, 2012

(54) ELECTRONIC DEVICE HAVING PERSONAL SYSTEM 2 (PS/2) PORT

(75) Inventors: ZHENG-HENG SUN, Tu-Cheng (TW); KANG WU, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD, Shenzhen City (CN)

(21) Appl. No.: 13/237,971

(22) Filed: Sep. 21, 2011

(30) Foreign Application Priority Data
May 19, 2011 (CN) 201110129990.5

(51) Int. Cl. G06F 1/16; H05K 7/00

(52) U.S. Cl. 361/679.45

(57) ABSTRACT

An electronic device includes a personal system 2 (PS/2) port, a route selection unit, and a signal identification unit. The PS/2 port may be electronically connected to a storage device through a universal serial bus (USB) interface. The signal identification unit identifies the storage device and then sends a control command to the route selection unit. The route selection unit distributes a USB data transmission route to the storage device according to the control command, so that the electronic device can exchange data with the storage device.

### BACKGROUND

1. Technical field

The disclosure generally relates to electronic devices, particularly to a desktop computer having personal system 2 (PS/2) ports.

2. Description of the Related Art

Most electronic devices, such as desktop computers, only have two universal serial bus (USB) ports and personal system 2 (PS/2 ports). These two USB ports are insufficient when the desktop computer simultaneously communicates with at least three storage devices (e.g., mobile phones). On the other hand, the PS/2 ports of the desktop computer remain idle when a keyboard or a mouse are not in use, and the inability of the storage device to communicate with the desktop computer via the PS/2 ports is a disadvantage.

Therefore, there is room for improvement within the art.

### BRIEF DESCRIPTION OF THE DRAWINGS

Many aspects of an exemplary desktop computer can be better understood with reference to the following drawings. The components in the drawings are not necessarily drawn to scale, the emphasis instead being placed upon clearly illustrating the principles of the disclosure. Moreover, in the drawings, like reference numerals designate corresponding parts throughout the several views. Wherever possible, the same reference numbers are used throughout the drawings to refer to the same or like elements of an embodiment.

FIG. 1 is a partly exploded view of a desktop computer comprising at least one port converter, according to an exemplary embodiment.

FIG. 2 is an enlarged view of the port converter as shown in FIG. 1.

FIG. 3 is an end view of a PS/2 port of the port converter as shown in FIG. 2.

FIG. 4 is an end view of a USB port of the port converter as shown in FIG. 2.

FIG. 5 is a view of the assembled desktop computer as shown in FIG. 1.

FIG. 6 is a block diagram of the desktop computer as shown in FIG. 1.

FIG. 7 is a view of a USB interface of a storage device.

### DETAILED DESCRIPTION

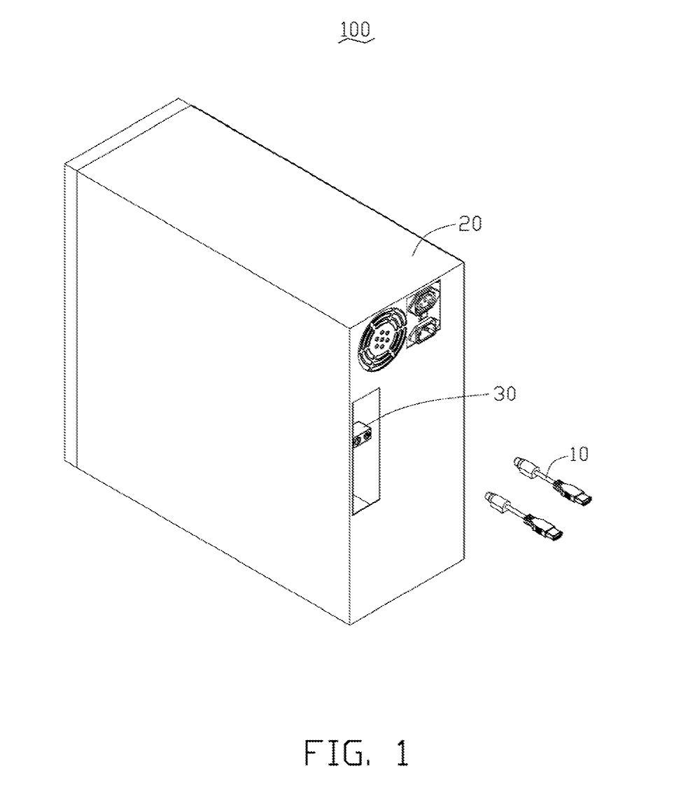

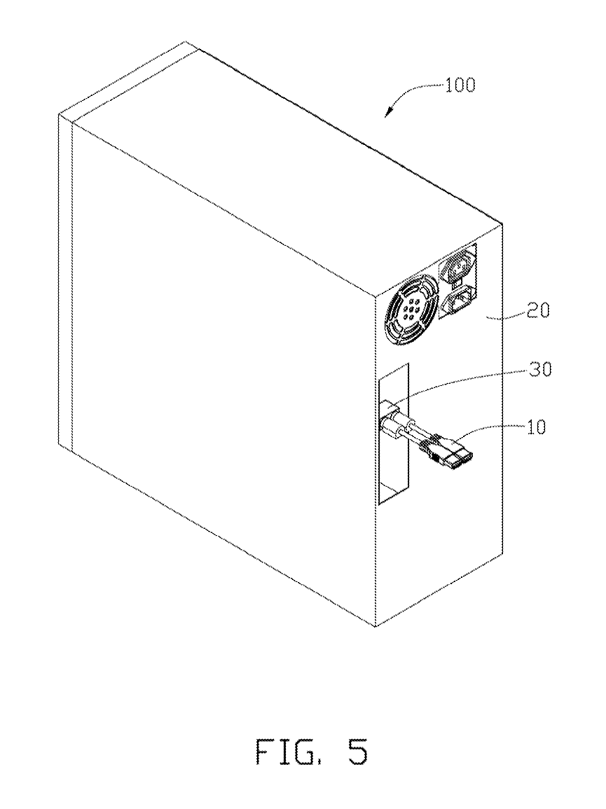

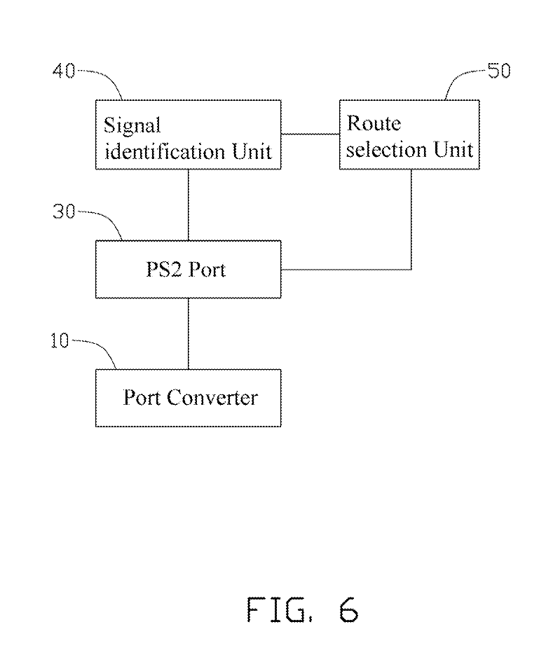

FIG. 1 and FIG. 5 show a desktop computer 100 comprising at least one port converter 10, according to an exemplary embodiment. The desktop computer 100 is operable to communicate with at least one storage device (not shown) through the at least one port converter 10. Referring to FIG. 6, the desktop computer 100 further includes a housing 20, at least one PS/2 port 30, a signal identification unit 40, and a route selection unit 50.

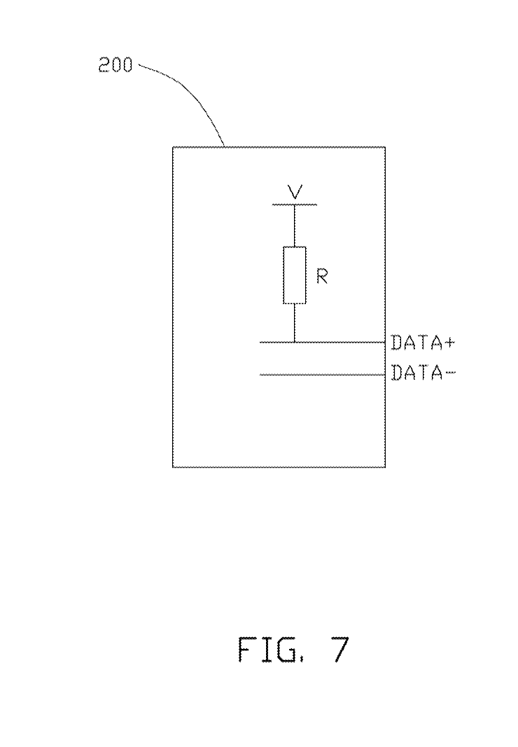

Referring to FIG. 7, the storage device can be a mobile phone, a personal digital assistant (PDA) or other portable electronic device that has a USB interface 200. The USB interface 200 includes a first data transmission pin DATA+ and a second data transmission pin DATA−. The storage device further includes a pull-up resistor R that can be electronically connected between a power supply V and the first data transmission pin DATA+ or the second data transmission pin DATA− according to a USB standard. In one exemplary embodiment, the pull-up resistor R can be about 1.5K ohm.

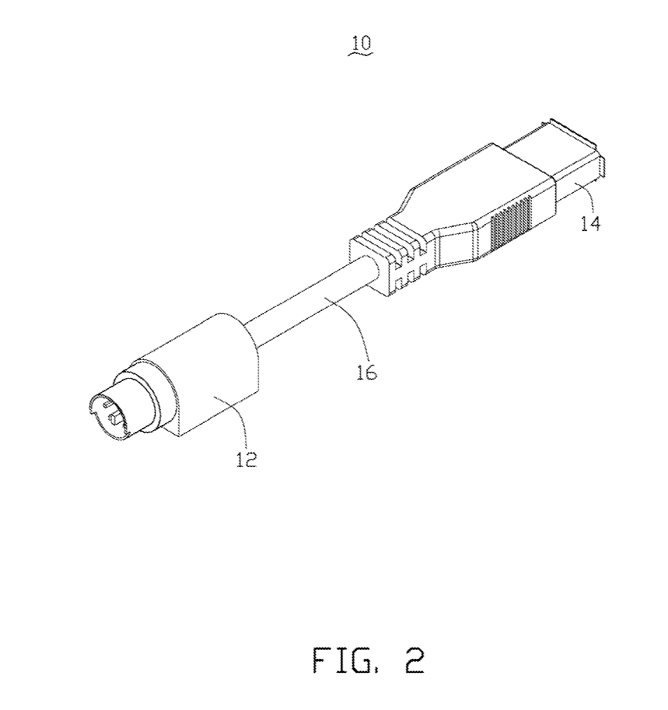

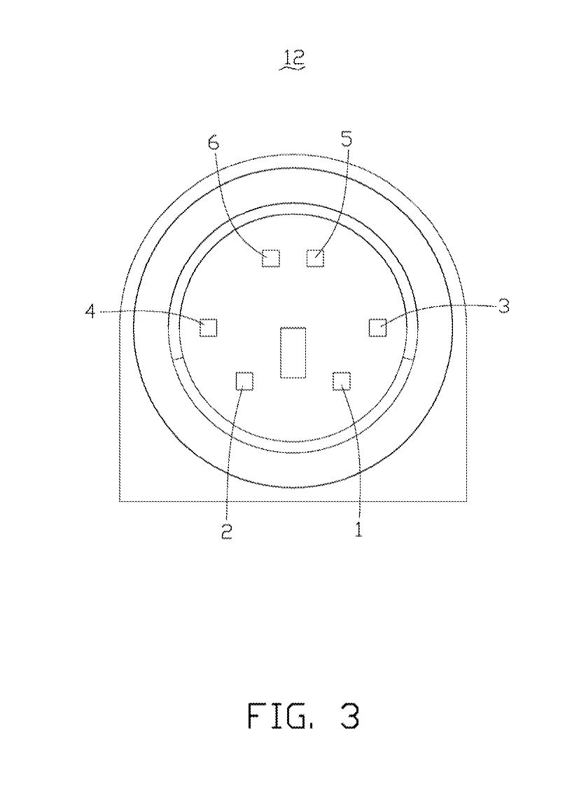

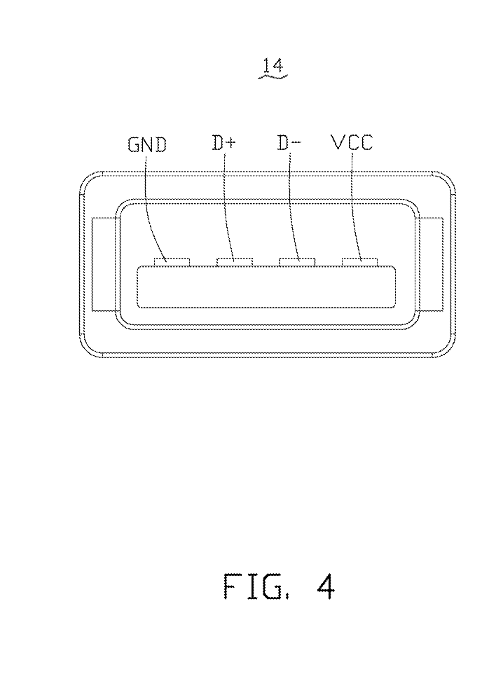

Referring to FIGS. 2-4, the port converter 10 includes a PS/2 connector 12, a USB connector 14, and a cable 16. The PS/2 connector 12 can electronically connect to the desktop computer 100 via the PS/2 port 30, and the PS/2 connector 12 includes a data pin 1, a ground pin 3, a power pin 4, a clock pin 5, and two unconnected pins 2, 6. The USB connector 14 can physically and electronically connect to the USB surface 200 of the storage device, and the USB connector 14 includes a power terminal VCC, a first data terminal D−, a second data terminal D+, and a ground terminal GND. When the USB connector 14 is connected to the storage device, the pull-up resistor R is electronically connected to the first data terminal D− or the second data terminal D+. The cable 16 connects the PS/2 connector 12 and the USB connector 14. Thus, the data pin 1 and the second data terminal D+, the clock pin 5 and the first data terminal D−, the ground pin 3 and the ground terminal GND, the power pin 4 and the power terminal VCC can be correctly interconnected via signal wires which are shielded and surrounded by the cable 16.

The at least one PS/2 port 30 is positioned at the rear side of the housing 20, the signal identification unit 40 and the route selection unit 50 are positioned on a motherboard of the desktop computer 100. The signal identification unit 40 is electronically connected to the at least one PS/2 port 30 and to the route selection unit 50.

The signal identification unit 40 may identify the storage device with the USB interface 200 that is electronically connected to the at least one PS/2 port 30 via the port converter 10. In one exemplary embodiment, the signal identification unit 40 can be a USB peripheral control microchip. When the storage device is electronically connected to the PS/2 port 30 via the port converter 10, the voltage of the data pin 1 or the clock pin 5 will be pulled up by the pull-up resistor R of the storage device, that is to say the data pin 1 or the clock pin 5 will output a high logic signal (about 3.3V in one example). Thus, the signal identification unit 40 identifies the storage device according to the high logic signal. Additionally, the signal identification unit 40 is operable to send a first control command to the route selection unit 50 when the signal identification unit 40 has identified the storage device. Moreover, when a PS/2 connector of a mouse or keyboard is connected to the PS/2 port 30, the signal identification unit 40 can identify the mouse or keyboard according to the PS/2 standard, and send a second control command to the route selection unit 50.

In one exemplary embodiment, the route selection unit 50 can be a multiplexer, which may provide a data transmission route to the storage device or to the mouse or keyboard according to either the first control command or the second control command Specifically, when the route selection unit 50 receives the first control command, the route selection unit 50 distributes a USB data transmission route to the storage device. The USB data transmission route can be from the PS/2 port 30 to a USB interface of the motherboard of the desktop computer 100, thus, effective communication between the storage device and the desktop computer 100 is enabled. When the route selection unit 50 receives the second control command, the route selection unit 50 distributes a PS/2 data transmission route to the mouse or keyboard. The PS/2 data transmission route can be from the PS/2 port 30 to a PS/2 interface of the motherboard of the desktop computer 100, thus, direct communication between the mouse or keyboard and the desktop computer 100 is enabled.

When the simultaneous connection of at least three storage devices is needed to exchange data with the desktop computer 100, users can allow at least one storage device to connect to the PS/2 port 30 via the port converter 10. Then, the pull-up resistor R is electronically connected to the first data terminal D− or the second data terminal D+. Thus, the data pin 1 or the clock pin 5 outputs a high logic signal. The signal identification unit 40 sends the first control command to the route selection unit 50 as soon as it receives the high logic signal. Then, the route selection unit 50 distributes the USB data transmission route to the at least one storage device so that the at least one storage device can communicate with the desktop computer 100.

The desktop computer 100 can exchange data with at least one storage device that has a USB interface 200 via the at least one PS/2 port 30 and the at least one port converter 10. Thus, the connection of at least three storage devices can be achieved.

Although numerous characteristics and advantages of the exemplary disclosure have been set forth in the foregoing description, together with details of the structure and function of the exemplary disclosure, the disclosure is illustrative only, and changes may be made in detail, especially in the matters of shape, size, and arrangement of parts within the principles of exemplary disclosure to the full extent indicated by the broad general meaning of the terms in which the appended claims are expressed.

What is claimed is:

1. An electronic device in communication with a storage device having an universal serial bus (USB) interface, the electronic device comprising:
at least one personal system 2 (PS/2) port;
a route selection unit; and
a signal identification unit electronically connected to the at least one PS/2 port and the route selection unit;
wherein when the at least one PS/2 port is electronically connected to the USB interface of the storage device, the signal identification unit identifies the storage device, and sends a control command, according to the identification, to the route selection unit, the route selection unit distributes a USB data transmission route to the storage device according to the control command, so that the electronic device communicates with the storage device via the USB data transmission route.

2. The electronic device as claimed in claim 1, wherein when a PS/2 connector of a mouse or a keyboard is connected to the at least one PS/2 port, the signal identification unit identifies the mouse or the keyboard, and sends another control command to the route selection unit, the route selection unit distributes a PS/2 data transmission route to the mouse or the keyboard.

3. The electronic device as claimed in claim 1, wherein the route selection unit and the signal identification unit are positioned on a motherboard of the electronic device.

4. The electronic device as claimed in claim 1, wherein the route selection unit is a multiplexer.

5. The electronic device as claimed in claim 1, further comprising at least one port converter, wherein said port converter includes a PS/2 connector, a USB connector, and a cable, the PS/2 connector connects to the electronic device via the at least one PS/2 port, the USB connector connects to the storage device via the USB interface, the cable connects the PS/2 connector and the USB connector.

6. The electronic device as claimed in claim 5, wherein the USB connector includes a first data terminal and a second data terminal, when the USB connector connects to the storage device, the first data terminal or the second data terminal is electronically connected to a pull-up resistor of the storage device.

7. The electronic device as claimed in claim 6, wherein the PS/2 connector includes a data pin and a clock pin, the data pin is electronically connected to the second data terminal, and the clock pin is electronically connected to the first data terminal.

8. The electronic device as claimed in claim 7, wherein when the USB connector connects to the storage device, the data pin or the clock pin outputs a high logic signal, and the signal identification unit identifies the storage device according to the high logic signal.

9. An electronic device communicating with a storage device, comprising:
a personal system 2 (PS/2) port;
a port converter;
a route selection unit, and
a signal identification unit electronically connected to the PS/2 port and the route selection unit;
wherein when the PS/2 port is electronically connected to the storage device via the port converter, the signal identification unit identifies the storage device, and sends a control command, according to the identification, to the route selection unit, the route selection unit distributes universal serial bus (USB) data transmission route to the storage device according to the control command, so that the electronic device communicates with the storage device via the USB data transmission route.

10. The electronic device as claimed in claim 9, wherein when a PS/2 connector of a mouse or a keyboard is connected to the PS/2 port, the signal identification unit sends another control command to the route selection unit, and the route selection unit distributes a PS/2 data transmission route to the mouse or the keyboard.

11. The electronic device as claimed in claim 9, wherein the port converter includes a PS/2 connector, a USB connector, and a cable, the PS/2 connector connects to the electronic device via the PS/2 port, the USB connector connects to a USB interface of the storage device, the cable connects the PS/2 connector and the USB connector.

12. The electronic device as claimed in claim 11, wherein the USB connector includes a first data terminal and a second data terminal, when the USB connector connects to the storage device, the first data terminal or the second data terminal is electronically connected to a pull-up resistor of the storage device.

13. The electronic device as claimed in claim 12, wherein the PS/2 connector includes a data pin and a clock pin, the data pin is electronically connected to the second data terminal, and the clock pin is electronically connected to the first data terminal.

14. The electronic device as claimed in claim 13, wherein when the USB connector connects to the storage device, the data pin or the clock pin outputs a high logic signal, and the signal identification unit identifies the storage device according to the high logic signal.

15. The electronic device as claimed in claim 9, wherein the electronic device is a desktop computer.
